(19) United States
(12) Patent Application Publication
(10) Pub. No.: US 2026/0150759 A1
(43) Pub. Date: May 28, 2026

(54) MICROELECTRONIC DEVICES AND RELATED METHODS

(71) Applicant: Micron Technology, Inc., Boise, ID (US)

(72) Inventors: Fatma Arzum Simsek-Ege, Boise, ID (US); James E. Davis, Meridian, ID (US); Souvick Mitra, Boise, ID (US)

(21) Appl. No.: 19/373,590

(22) Filed: Oct. 29, 2025

Related U.S. Application Data
(60) Provisional application No. 63/723,847, filed on Nov. 22, 2024.

(51) Int. Cl. H01L 25/18; H01L 23/00; H01L 23/48; H01L 23/522; H01L 23/66; H10B 80/00; H10D 80/30

(52) U.S. Cl. CPC H10W 90/00; H10B 80/00; H10D 80/30; H10W 20/20; H10W 44/20; H10W 20/496; H10W 44/209; H10W 44/248; H10W 80/312; H10W 80/327; H10W 90/792

(57) ABSTRACT

A microelectronic device includes a memory array structure including an array region including memory cells within a horizontal area of the array region, each of the memory cells having a access device and a storage node device vertically underlying and coupled to the access device, a control circuitry structure vertically overlying and attached to the memory array structure at a boundary of the memory array structure vertically closer to the access devices of the memory cells than the storage node devices of the memory cells. The control circuitry structure includes an antenna diode structure formed within a semiconductor material. The microelectronic device further includes a shared carrier including a cell plate over which the first memory array structure is attached and a contact assembly in contact with the cell plate. The contact assembly includes an interconnect structure in contact with the first doped region of the antenna diode structure.

### CROSS-REFERENCE TO RELATED APPLICATIONS

This application claims the benefit under 35 U.S.C. § 119(e) of U.S. Provisional Patent Application Ser. No. 63/723,847, filed Nov. 22, 2024, the disclosure of which is hereby incorporated herein in its entirety by this reference.

### TECHNICAL FIELD

The disclosure, in various embodiments, relates generally to the field of microelectronic device design and fabrication. More specifically, the disclosure relates to methods of forming microelectronic devices from independently formed microelectronic device structures, and to related microelectronic devices and electronic systems.

### BACKGROUND

Microelectronic device designers often desire to increase the level of integration or density of features within a microelectronic device by reducing the dimensions of the individual features and by reducing the separation distance between neighboring features. In addition, microelectronic device designers often desire to design architectures that are not only compact, but offer performance advantages, as well as simplified designs.

One example of a microelectronic device is a memory device. Memory devices are generally provided as internal integrated circuits in computers or other electronic devices. There are many types of memory devices including, but not limited to, volatile memory devices, such as dynamic random-access memory (DRAM) devices; and non-volatile memory devices such as NAND Flash memory devices. A typical memory cell of a DRAM device includes one access device, such as a transistor, and one memory storage structure, such as a capacitor. Modern applications for semiconductor devices can employ significant quantities of memory cells, arranged in memory arrays exhibiting rows and columns of the memory cells. The memory cells may be electrically accessed through digit lines (e.g., bit lines, data lines) and word lines (e.g., access lines) arranged along the rows and columns of the memory cells of the memory arrays. Memory arrays can be two-dimensional (2D) so as to exhibit a single deck (e.g., a single tier, a single level) of the memory cells, or can be three-dimensional (3D) so as to exhibit multiple decks (e.g., multiple levels, multiple tiers) of the memory cells.

Control logic devices within a base control logic structure underlying a memory array of a memory device have been used to control operations (e.g., access operations, read operations, write operations) of the memory cells of the memory device. An assembly of the control logic devices may be provided in electrical communication with the memory cells of the memory array by way of routing and first interconnect structures. However, processing conditions (e.g., temperatures, pressures, materials) for the formation of the memory array over the base control logic structure can limit the configurations and performance of the control logic devices within the base control logic structure. In addition, the quantities, dimensions, and arrangements of the different control logic devices employed within the base control logic structure can also undesirably impede reductions to the size (e.g., horizontal footprint) of the memory device, and/or improvements in the performance (e.g., faster memory cell ON/OFF speed, lower threshold switching voltage requirements, faster data transfer rates, lower power consumption) of the memory device. Furthermore, as the density and complexity of the memory array have increased, so has the complexity of the control logic devices. In some instances, the control logic devices consume more real estate than the memory devices, reducing the memory density of the memory device. Moreover, capacitors for regulating and supplying voltages to the control logic devices can require substantial footprints.

### BRIEF DESCRIPTION OF THE DRAWINGS

For a detailed understanding of the disclosure, reference should be made to the following detailed description, taken in conjunction with the accompanying drawings, in which like elements have generally been designated with like numerals, and wherein:

FIG. 1 shows a simplified, partial plan view of a memory array structure at a processing stage of a method of forming a microelectronic device, according to one or more embodiments of the disclosure;

FIG. 2 shows a simplified partial plan view of a control circuitry structure at a processing stage of the method of forming a microelectronic device, in accordance with embodiments of the disclosure;

FIG. 3 is a diagram showing different vertical cross-sectional views of the memory assembly as shown in FIG. 1 and FIG. 2, taken about lines A-A and B-B of FIG. 1 and FIG. 2;

FIG. 4 shows a diagram depicting different vertical cross-sectional views of a memory array structure of a microelectronic device at a processing stage of forming the microelectronic device, according to one or more embodiments of the disclosure;

FIG. 5 shows a diagram depicting different vertical cross-sectional views of a control circuitry structure of a microelectronic device at a processing stage of forming the microelectronic device, according to one or more embodiments of the disclosure;

FIG. 6 shows a diagram depicting a vertical cross-sectional view of a contact assembly of a microelectronic device at a processing stage of forming the microelectronic device, according to one or more embodiments of the disclosure;

FIG. 7A through FIG. 7C include simplified, vertical cross-sectional views of an antenna diode structure at different processing stages of a method of forming the antenna diode structure, according to one or more embodiments of the disclosure;

FIG. 8 includes a simplified, vertical cross-sectional view of an antenna diode structure according to one or more embodiments of the disclosure;

FIG. 9 includes a simplified, vertical cross-sectional view of an antenna diode structure according to one or more embodiments of the disclosure; and

FIG. 10 is a schematic block diagram of an electronic system, in accordance with an embodiment of the disclosure.

### DETAILED DESCRIPTION

The illustrations included herewith are not meant to be actual views of any particular systems, microelectronic structures, microelectronic devices, or integrated circuits thereof, but are merely idealized representations that are employed to describe embodiments herein. Elements and features common between figures may retain the same numerical designation except that, for ease of following the description, reference numerals begin with the number of the drawing on which the elements are introduced or most fully described.

The following description provides specific details, such as material types, material thicknesses, and processing conditions in order to provide a thorough description of embodiments described herein. However, a person of ordinary skill in the art will understand that the embodiments disclosed herein may be practiced without employing these specific details. Indeed, the embodiments may be practiced in conjunction with conventional fabrication techniques employed in the semiconductor industry. In addition, the description provided herein does not form a complete process flow for manufacturing a microelectronic device (e.g., a semiconductor device, a memory device), apparatus, or electronic system, or a complete microelectronic device, apparatus, or electronic system. The structures described below do not form a complete microelectronic device, apparatus, or electronic system. Only those process acts and structures necessary to understand the embodiments described herein are described in detail below. Additional acts to form a complete microelectronic device, apparatus, or electronic system from the structures may be performed by conventional techniques.

As used herein, the term “homogeneous” means relative amounts of elements included in a feature (e.g., a material, a structure) do not vary throughout different portions (e.g., different horizontal portions, different vertical portions) of the feature. Conversely, as used herein, the term “heterogeneous” means relative amounts of elements included in a feature (e.g., a material, a structure) vary throughout different portions of the feature. If a feature is heterogeneous, amounts of one or more elements included in the feature may vary stepwise (e.g., change abruptly), or may vary continuously (e.g., change progressively, such as linearly, parabolically) throughout different portions of the feature. The feature may, for example, be formed of and include a stack of at least two different materials.

The materials described herein may be formed by conventional techniques including, but not limited to, spin coating, blanket coating, chemical vapor deposition (CVD), atomic layer deposition (ALD), plasma enhanced ALD, physical vapor deposition (PVD), plasma enhanced chemical vapor deposition (PECVD), or low pressure chemical vapor deposition (LPCVD). Alternatively, the materials may be grown in situ. Depending on the specific material to be formed, the technique for depositing or growing the material may be selected by a person of ordinary skill in the art. The removal of materials may be accomplished by any suitable technique including, but not limited to, etching, abrasive planarization (e.g., chemical-mechanical planarization), or other known methods unless the context indicates otherwise.

As used herein, the term “configured” refers to a size, shape, material composition, orientation, and arrangement of one or more of at least one structure and at least one apparatus facilitating operation of one or more of the structure and the apparatus in a predetermined way.

As used herein, the terms “longitudinal,” “vertical,” “lateral,” and “horizontal” are in reference to a major plane of a substrate (e.g., base material, base structure, base construction, etc.) in or on which one or more structures and/or features are formed and are not necessarily defined by Earth's gravitational field. A “lateral” or “horizontal” direction is a direction that is substantially parallel to the major plane of the substrate, while a “longitudinal” or “vertical” direction is a direction that is substantially perpendicular to the major plane of the substrate. The major plane of the substrate is defined by a surface of the substrate having a relatively large area compared to other surfaces of the substrate. With reference to the figures, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, the term “proximate,” when utilized to describe positions of elements relative to each other, means that the elements are relatively close or near to each other. For example, where a first element is proximate to a horizontal boundary of a second element, the first element is closer to that horizontal boundary than other horizontal boundaries of the second element.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped, etc.) and the spatially relative descriptors used herein interpreted accordingly.

As used herein, features (e.g., regions, materials, structures, devices) described as “neighboring” one another means and includes features of the disclosed identity (or identities) that are located most proximate (e.g., closest to) one another. Additional features (e.g., additional regions, additional materials, additional structures, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, the term “memory device” means and includes microelectronic devices exhibiting memory functionality, but not necessarily limited to memory functionality. Stated another way, and by way of example only, the term “memory device” means and includes not only conventional memory (e.g., conventional volatile memory, such as conventional DRAM; conventional non-volatile memory, such as conventional NAND memory), but also includes an application specific integrated circuit (ASIC) (e.g., a system on a chip (SoC)), a microelectronic device combining logic and memory, and a graphics processing unit (GPU) incorporating memory.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al)), an alloy (e.g., a Co-based alloy, an Fe-based alloy, an Ni-based alloy, an Fe-and Ni-based alloy, a Co-and Ni-based alloy, an Fe-and Co-based alloy, a Co-and Ni-and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively-doped semiconductor material (e.g., conductively-doped polysilicon, conductively-doped germanium (Ge), conductively-doped silicon germanium (SiGe)). In addition, a “conductive structure” means and includes a structure formed of and including a conductive material.

As used herein, “insulative material” means and includes electrically insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), and at least one dielectric carboxynitride material (e.g., a silicon carboxynitride (SiOₓC_{z}N_{y})). In addition, an “insulative structure” means and includes a structure formed of and including an insulative material.

As used herein, the term “sacrificial material” means and includes a material that is formed and/or employed during a fabrication process, but which is subsequently removed, in whole or in part, prior to completion of the fabrication process. A “partially-sacrificial” material means and includes a sacrificial material from which only one or more portions is or are removed prior to completion of the fabrication process. A “wholly-sacrificial” material means and includes a sacrificial material that is substantially entirely removed prior to completion of the fabrication process.

As used herein, “semiconductor material” and “semiconductive material” refers to a material having an electrical conductivity between those of insulative materials and conductive materials. For example, a semiconductor material may have an electrical conductivity of between about 10⁻⁸ Siemens per centimeter (S/cm) and about 10⁴ S/cm (10⁶ S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., Al_{X}Ga_{1-X}As), and quaternary compound semiconductor materials (e.g., Ga_{X}In_{1-X}As_{Y}P_{1-Y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials such as zinc tin oxide (ZnₓSn_{y}O, commonly referred to as “ZTO”), indium zinc oxide (InₓZn_{y}O, commonly referred to as “IZO”), zinc oxide (ZnₓO), indium gallium zinc oxide (InₓGa_{y}Zn_{z}O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), indium oxide (InₓO), tin oxide (SnₓO), titanium oxide (TiₓO), zinc oxide nitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), and other similar materials. In addition, a “semiconductor structure” and a “semiconductive structure” mean and include a structure formed of and including semiconductor material.

Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions.

Unless the context indicates otherwise, the materials described herein may be formed by any suitable technique including, but not limited to, spin coating, blanket coating, chemical vapor deposition (CVD), plasma enhanced CVD (PECVD), atomic layer deposition (ALD), plasma enhanced ALD (PEALD), physical vapor deposition (PVD) (e.g., sputtering), or epitaxial growth. Depending on the specific material to be formed, the technique for depositing or growing the material may be selected by a person of ordinary skill in the art. In addition, unless the context indicates otherwise, removal of materials described herein may be accomplished by any suitable technique including, but not limited to, etching (e.g., dry etching, wet etching, vapor etching), ion milling, abrasive planarization (e.g., chemical-mechanical planarization (CMP)), or other known methods.

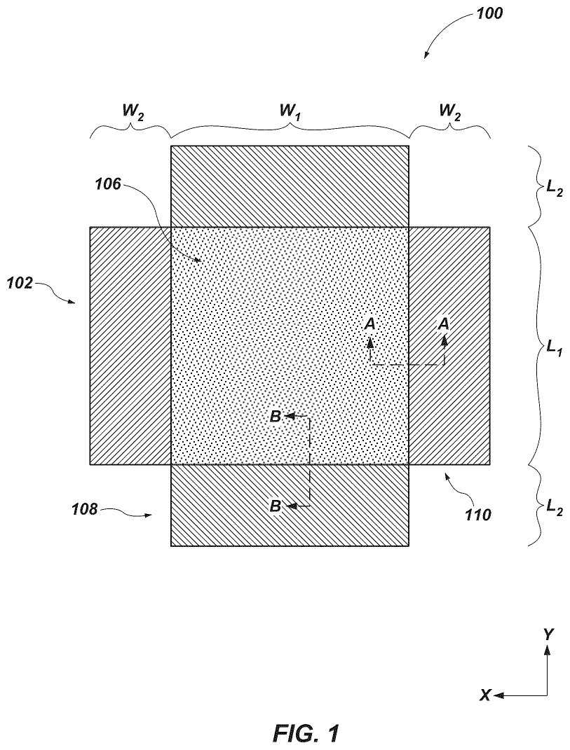

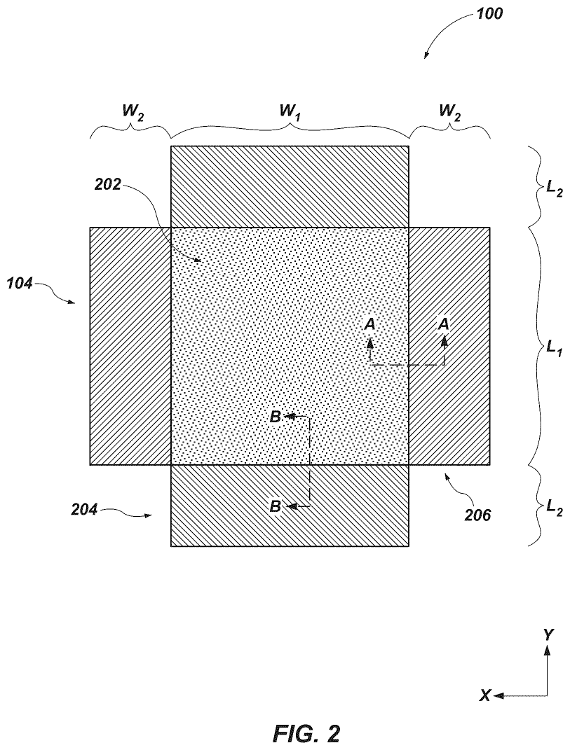

FIG. 1 is a simplified, partial plan view of a memory array structure 102 of a microelectronic device 100 at a processing stage of forming the microelectronic device 100 (e.g., a memory device, such as Dynamic Random Access Memory (DRAM) device, an HRAM device, an FeRAM device, an SDRAM device, an MRAM device), in accordance with embodiments of the disclosure. FIG. 2 is a simplified, partial plan view of a control circuitry structure 104 (e.g., a second wafer, a second die) of the microelectronic device 100 at a processing stage of forming at a processing stage of the method of forming the microelectronic device, in accordance with embodiments of the disclosure. The control circuitry structure 104 may be formed separately from memory array structure 102 and is configured to be attached (e.g., bonded) to the memory array structure 102, as described in further detail below. With the description provided below, it will be readily apparent to one of ordinary skill in the art that the methods and structures described herein may be used to form various devices and electronic systems.

Referring to FIG. 1 and FIG. 2 together, the memory array structure 102 may include an array region 106, digit line exit region 108 (also referred to as “digit line (DL) contact socket regions”) horizontally neighboring the array region 106 in a Y-direction, and word line exit regions 110 (also referred to as “word line (WL) contact socket regions”) horizontally neighboring the array region 106 in an X-direction orthogonal to the Y-direction. The array region 106, the digit line exit region 108, and the word line exit regions 110 are each described in further detail below.

The control circuitry structure 104 may be formed to include a control circuitry region 202, first peripheral regions 204 horizontally neighboring the control circuitry region 202 in the Y-direction, and second peripheral regions 206 horizontally neighboring the control circuitry region 202 in an X-direction orthogonal to the Y-direction. The control circuitry region 202, the first peripheral regions 204, and the second peripheral regions 206 are each described in further detail below.

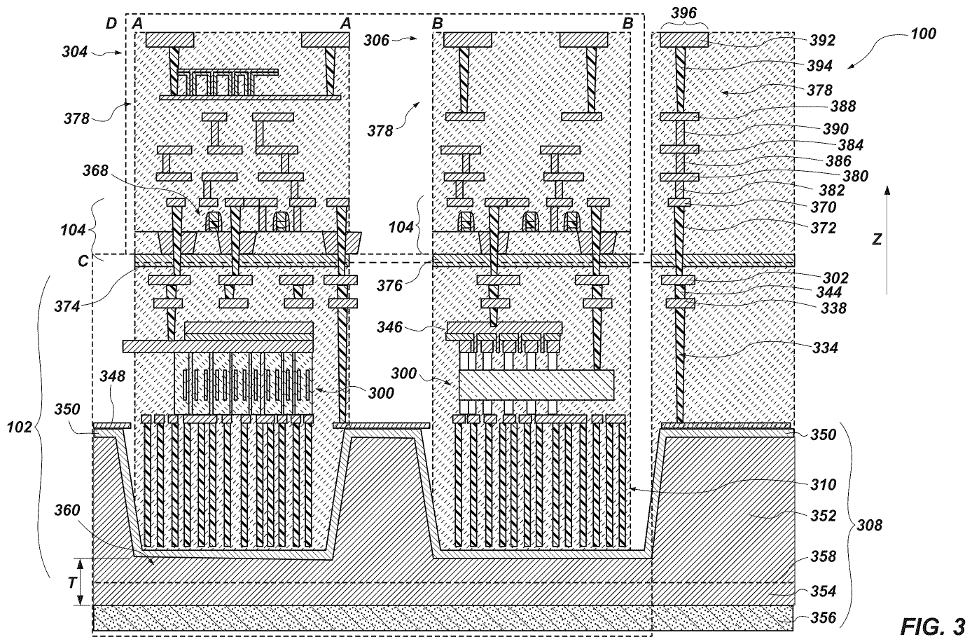

FIG. 3 is a diagram showing different vertical cross-sectional views of the microelectronic device 100 as shown in FIG. 1 and FIG. 2, taken about lines A-A and B-B of FIG. 1 and FIG. 2. The vertical cross section of the microelectronic device 100 taken about line A-A is a view of a XZ-plane of a portion of a microelectronic device 100 horizontally overlapping the array region 106 and one of the digit line exit regions 108 of the memory array structure 102 and overlapping the control circuitry region 202 and one of the second peripheral regions 206 of the control circuitry structure 104. The vertical cross section of the microelectronic device 100 taken about line B-B is a view of an YZ-plane of an additional portion of a microelectronic device 100 overlapping the array region 106 and one of the word line exit regions 110 of the memory array structure 102 and overlapping the control circuitry region 202 and one of the first peripheral regions 204 of the control circuitry structure 104. While lines A-A and B-B are described in relation to a single microelectronic device 100 within FIG. 1 and FIG. 2, the disclosure is not so limited, and in some embodiments, the vertical cross-sectional view taken about line A-A is from a first microelectronic device (e.g., a first assembly, tile, patch, or subarray), and the vertical cross-sectional view taken about line B-B is from a neighboring second microelectronic device (e.g., a second assembly, tile, patch, or subarray).

Referring to FIG. 1 specifically, the array region 106 of the microelectronic device 100 is a horizontal area of the microelectronic device 100 including an array of the memory cells (e.g., an array of DRAM cells), as described in further detail below. The microelectronic device 100 may include a desired quantity and distribution of array regions 106. For clarity and ease of understanding of the drawings and related description, FIG. 1 depicts the microelectronic device 100 as including one (1) array region 106, but the microelectronic device 100 may be formed to include multiple (e.g., more than one (1)) array regions 106 horizontally offset (e.g., in one or more of the X-direction and the Y-direction) from one another. For example, the microelectronic device 100 may include greater than or equal to four (4) array regions 106, greater than or equal to eight (8) array regions 106, greater than or equal to sixteen (16) array regions 106, greater than or equal to thirty-two (32) array regions 106, greater than or equal to sixty-four (64) array regions 106, greater than or equal to one hundred twenty-eight (128) array regions 106, greater than or equal to two hundred fifty-six (256) array regions 106, greater than or equal to five hundred twelve (512) array regions 106, or greater than or equal to one thousand twenty-four (1024) array regions 106.

As shown in FIG. 1, the array region 106 of the microelectronic device 100 may have a first width W₁ in the X-direction and a first length L₁ in the Y-direction orthogonal to the X-direction. In some embodiments, the first width W₁ is substantially equal to the first length L₁. In additional embodiments, the first width W₁ is different than (e.g., greater than, less than) the first length L₁.

The digit line exit regions 108 of the microelectronic device 100 may include horizontal areas of the microelectronic device 100 configured include portions of digit line structures (e.g., bit line structures, data line structures) within horizontal boundaries thereof. For an individual digit line exit region 108, at least some digit line structures operatively associated with the array region 106 horizontally neighboring the digit line exit region 108 in the Y-direction may have portions within the horizontal area of the digit line exit region 108. In addition, the digit line exit region 108 may also be configured to include conductive contact structures and conductive routing structures within the horizontal areas thereof that are operatively associated with the digit line structures. As described in further detail below, some of the conductive contact structures within the digit line exit regions may couple the digit line structures to control logic circuitry of control logic devices (e.g., sense amplifier (SA) devices) to subsequently be provided vertically over the microelectronic device 100. In some embodiments, the digit line exit regions 108 respectively horizontally extend in the X-direction. An individual array region 106 may be horizontally interposed between horizontally neighboring digit line exit regions 108 in the Y-direction.

As shown in FIG. 1, the digit line exit regions 108 of the microelectronic device 100 may respectively have the first width W₁ in the X-direction and a second length L₂ in the Y-direction orthogonal to the X-direction. The second length L₂ of an individual digit line exit region 108 is smaller than the first width W₁ of the digit line exit region 108. In addition, the second length L₂ of the digit line exit region 108 is smaller than the first length L₁ of an individual array region 106 of the microelectronic device 100.

The word line exit regions 110 of the microelectronic device 100 may include additional horizontal areas of the microelectronic device 100 including portions of the word line structures (e.g., gate electrodes, access line structures) within horizontal boundaries thereof. For an individual word line exit region 110, at least some word line structures operatively associated with the array region 106 horizontally neighboring the word line exit region 110 in the X-direction may have portions within the horizontal area of the word line exit region 110. In addition, the word line exit regions 110 may also include additional conductive contact structures and additional conductive routing structures within the horizontal areas thereof that are operatively associated with the word line structures. As described in further detail below, some of the additional conductive contact structures within the word line exit regions 110 may couple the word line structures to additional control logic circuitry of additional control logic devices (e.g., sub word line driver (SWD) devices) to subsequently be provided vertically over the microelectronic device 100. In some embodiments, the word line exit regions 110 respectively horizontally extend in the Y-direction. An individual array region 106 may be horizontally interposed between horizontally neighboring word line exit regions 110 in the X-direction.

As shown in FIG. 1, the word line exit regions 110 of the microelectronic device 100 may respectively have a second width W₂ in the X-direction and the first length L₁ in the Y-direction orthogonal to the Z-direction. The second width W₂ of an individual word line exit region 110 is smaller than the first length L₁ of the word line exit region 110. In addition, the second width W₂ of the word line exit region 110 is smaller than the first width W₁ of an individual array region 106 of the microelectronic device 100.

Referring specifically to FIG. 2, the control circuitry region 202 of the control circuitry structure 104 includes control logic circuitry of the control circuitry structure 104 within a horizontal area thereof. The control logic circuitry of the control circuitry region 202 of the control circuitry structure 104 may be configured to be operatively associated with circuitry (e.g., memory cells) of the microelectronic device 100, as described in further detail below. In some embodiments, the control circuitry region 202 is configured to at least partially (e.g., substantially) horizontally overlap a respective array region 106 (FIG. 1) of the microelectronic device 100 following subsequent attachment of the control circuitry structure 104 to the microelectronic device 100, as also described in further detail below.

For clarity and ease of understanding of the drawings and related description, FIG. 2 depicts the control circuitry structure 104 as including one (1) control circuitry region 202, but the control circuitry structure 104 may be formed to include multiple (e.g., more than one (1)) control circuitry regions 202 horizontally offset (e.g., in one or more of the X-direction and the Y-direction) from one another. For example, the control circuitry structure 104 may include greater than or equal to four (4) control circuitry regions 202, greater than or equal to eight (8) control circuitry regions 202, greater than or equal to sixteen (16) control circuitry regions 202, greater than or equal to thirty-two (32) control circuitry regions 202, greater than or equal to sixty-four (64) control circuitry regions 202, greater than or equal to one hundred twenty-eight (128) control circuitry regions 202, greater than or equal to two hundred fifty-six (302) control circuitry regions 202, greater than or equal to five hundred twelve (512) control circuitry regions 202, or greater than or equal to one thousand twenty-four (1024) control circuitry regions 202. In some embodiments, a quantity of the control circuitry regions 202 of the control circuitry structure 104 substantially equals a quantity of the array regions 106 (FIG. 1) of the microelectronic device 100.

The first peripheral regions 204 of the control circuitry structure 104 respectively include additional circuitry (e.g., peripheral circuitry) of the control circuitry structure 104 within a horizontal area thereof. In some embodiments, the first peripheral regions 204 are configured to at least partially (e.g., substantially) horizontally overlap respective digit line exit regions 108 (FIG. 1) of the memory array structure 102 (FIG. 1) following subsequent attachment of the control circuitry structure 104 to the memory array structure 102 (FIG. 1), as described in further detail below. In some embodiments, a quantity of the first peripheral regions 204 of the control circuitry structure 104 substantially equals a quantity of the digit line exit regions 108 (FIG. 1) of the memory array structure 102 (FIG. 1). As shown in FIG. 2, the first peripheral regions 204 may respectively horizontally extend in the X-direction. An individual control circuitry region 202 of the control circuitry structure 104 may be horizontally interposed between horizontally neighboring first peripheral regions 204 of the control circuitry structure 104 in the Y-direction.

The second peripheral regions 206 of the control circuitry structure 104 respectively include further circuitry (e.g., further peripheral circuitry) of the control circuitry structure 104 within a horizontal area thereof. In some embodiments, the second peripheral regions 206 are configured to at least partially (e.g., substantially) horizontally overlap respective word line exit regions 110 (FIG. 1) of the memory array structure 102 (FIG. 1) following subsequent attachment of the control circuitry structure 104 to the memory array structure 102 (FIG. 1), as described in further detail below. In some embodiments, a quantity of the second peripheral regions 206 of the control circuitry structure 104 substantially equals a quantity of the word line exit regions 110 (FIG. 1) of the memory array structure 102 (FIG. 1). As shown in FIG. 1, the second peripheral regions 206 may respectively horizontally extend in the Y-direction. An individual control circuitry region 202 of the control circuitry structure 104 may be horizontally interposed between horizontally neighboring second peripheral regions 206 of the control circuitry structure 104 in the X-direction.

Still referring to FIG. 2, the control circuitry region 202 of the control circuitry structure 104 may respectively have the first width W₁ in the X-direction and the first length L₁ in the Y-direction orthogonal to the X-direction. Furthermore, the first peripheral regions 204 of the control circuitry structure 104 may respectively have the first width W₁ in the X-direction and the second length L₂ in the Y-direction; and the second peripheral regions 206 of the control circuitry structure 104 may respectively have the second width W₂ in the X-direction and the first length L₁ in the Y-direction. Accordingly, a horizontal area of an individual control circuitry region 202 may be substantially the same as a horizontal area of an individual array region 106 (FIG. 1) of the microelectronic device 100 (FIG. 1). A horizontal area of an individual first peripheral region 204 may be substantially the same as a horizontal area of an individual digit line exit regions 108 (FIG. 1) of the memory array structure 102 (FIG. 1), and a horizontal area of an individual second peripheral region 206 may be substantially the same as a horizontal area of an individual word line exit region 110 (FIG. 1) of the memory array structure 102 (FIG. 1).

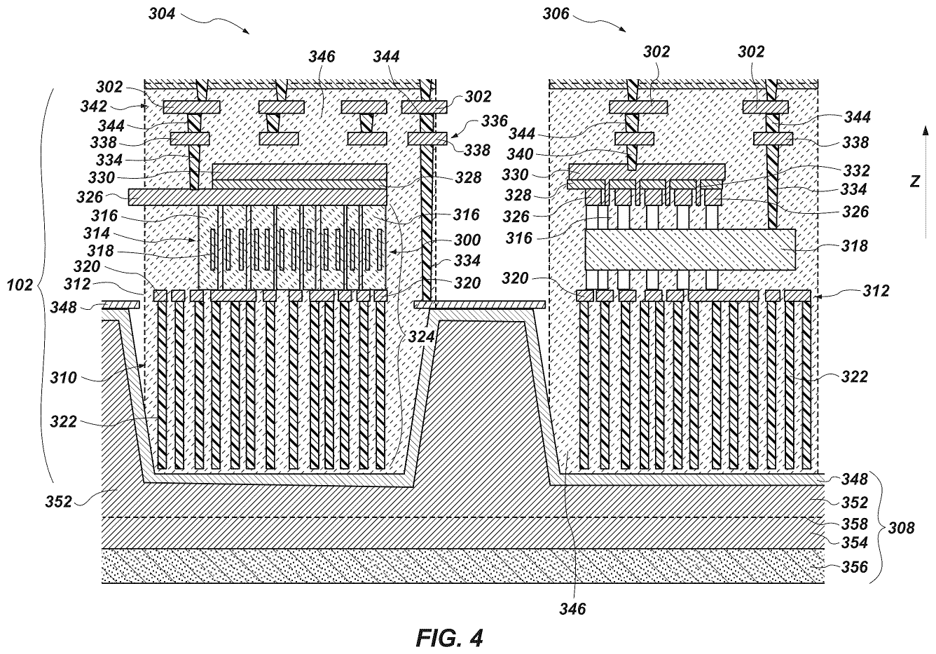

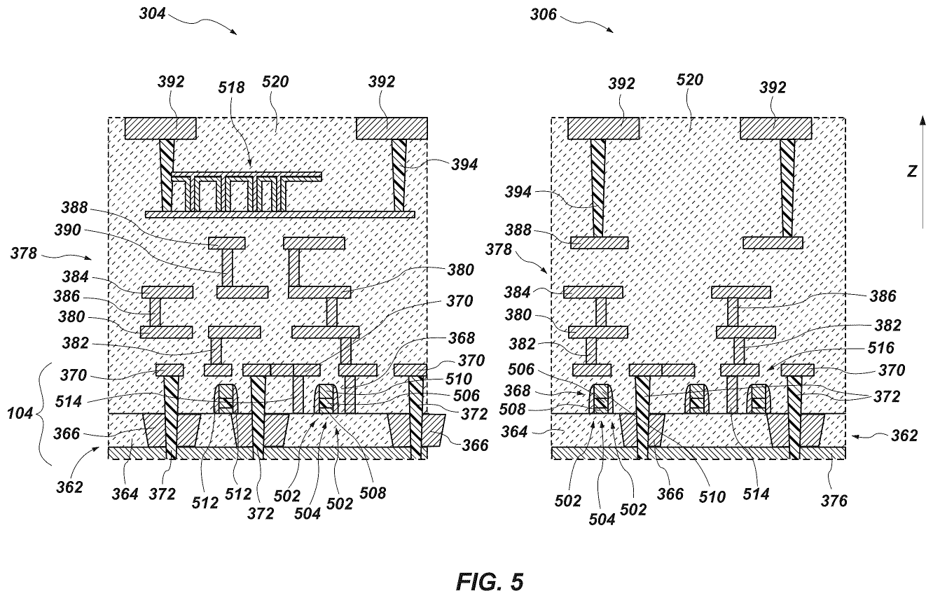

As noted above, FIG. 3 is a diagram showing different vertical cross-sectional views of the microelectronic device 100 as shown in FIG. 1 and FIG. 2, taken about lines A-A and B-B of FIG. 1 and FIG. 2. FIG. 4 is an enlarged, partial cross-sectional view of the area of the microelectronic device 100 of FIG. 3 within box C of FIG. 3. FIG. 5 is an enlarged, partial cross-sectional view of the area of the microelectronic device 100 of FIG. 3 within box D of FIG. 3.

Referring to FIG. 3 through FIG. 5 together, the microelectronic device 100 may include a first memory assembly 304 and a neighboring second memory assembly 306 within horizontal area of a patch region of a bank region of the microelectronic device 100. For instance, the microelectronic device 100 may include the first memory assembly 304 and the second memory assembly 306 oriented on and overlying portions of a shared carrier 308. As will be recognized by one of ordinary skill in the art, while only two memory assemblies are depicted in FIG. 3, the disclosure is not so limited, and the microelectronic device 100 and patch regions of the microelectronic device 100 may include additional memory assemblies.

Each of the first memory assembly 304 and the second memory assembly 306 may include a memory array structure 102 and a control circuitry structure 104 bonded to the memory array structure 102. The memory array structure 102 may include an access device structure 300, a multi-storage node structure 310, and a redistribution layer (RDL) tier 312 vertically interposed between the access device structure 300 and the multi-storage node structure 310.

The access device structures 300 may include vertical access devices 314. An individual vertical access device 314 may include a semiconductor pillar 316 including a channel region comprising an undoped region of the semiconductor pillar 316, a drain region comprising the first doped region of the semiconductor pillar 316, and a source region comprising the second doped region of the semiconductor pillar. In addition, the vertical access devices 314 may include a gate electrode (e.g., a word line structure 318) and a gate dielectric material (e.g., a dielectric liner material). A given word line structure 318 may be utilized as a gate electrode for multiple vertical access devices 314.

The RDL tier 312 may include redistribution material (RDM) structures 320. The RDM structures 320 may, for example, facilitate a horizontal arrangement (e.g., a hexagonal close packed arrangement) of storage node devices (e.g., capacitors) of the multi-storage node structure 310 (described below) that is different than a horizontal arrangement of contact structures of the semiconductor pillars 316 of the access devices 314, while still electrically connecting the contact structures semiconductor pillars 316 to the storage node devices. The RDM structures 320 may be formed of and include one or more of W, Ru, Mo, and TiN_{y}.

The multi-storage node structure 310 may include multiple storage node devices 322 (e.g., capacitors). The storage node devices 322 may be in electrical contact with the RDM structures 320, and, hence, with the semiconductor pillars 316 of the access devices 314. The storage node devices 322 may be coupled to the semiconductor pillars 316 by way of contact structures (e.g., pucks) and the RDM structures 320 to form memory cells 324 (e.g., DRAM cells).

Each memory cell 324 may individually include one of the access devices 314, one of the storage node devices 322, and one of the RDM structures 320. The storage node devices 322 may individually be formed and configured to store a charge representative of a programmable logic state of the memory cell 324 including the storage node device 322.

In some embodiments, the storage node devices 322 include capacitors. During use and operation, a charged capacitor may represent a first logic state, such as a logic 1; and an uncharged capacitor may represent a second logic state, such as a logic 0. Each of the storage node devices 322 may, for example, be formed to include a first electrode (e.g., a bottom electrode), a second electrode (e.g., a top electrode), and a first dielectric material between the first electrode and the second electrode. For instance, each of the storage node devices 322 may include a metal-insulator-metal (MIM) capacitor. As another example, each of the storage node devices 322 may include a metal-insulator-semiconductor (MIS) capacitor. The collection of memory cells 324 may form a memory array.

The multi-storage node structure 310 may further include a conductive material formed between neighboring storage node devices 322. The conductive material may substantially cover and surround the storage node devices 322. The second electrode of the storage node devices 322 may be operatively positioned (e.g., embedded) within the conductive material. The conductive material may include any of the conductive materials described herein. For instance, the conductive material may include polysilicon or conductively-doped silicon germanium (SiGe).

Referring still to FIG. 3, the memory array structure 102 may further include digit line structures 326 (e.g., bit line structures, data line structures) formed on or over the semiconductor pillars 316 of the access devices 314 of the access device structure 300. In particular, the digit line structures 326 are formed vertically on or over each of the semiconductor pillars 316. The digit line structures 326 may be formed of and include a conductive material. The conductive material may include one or more conductive materials. In some embodiments, the conductive material includes tungsten, either alone or in combination with one or more conductive barrier materials (e.g., oxidation resistant materials which protect the tungsten from oxidation in embodiments in which the tungsten may be exposed to oxygen).

The digit line structures 326 may be formed to any suitable dimensions (e.g., width, thickness). By way of example, the digit line structures 326 may individually be formed to a width, in a Y-direction, equal to about the width of an individual semiconductor pillars 316 (e.g., in a range of from about 10 nm to about 30 nm). The digit line structures 326 may be formed to any suitable pitch. The digit line structures 326 may be spaced apart from one another by a distance equal to about the distance between the semiconductor pillars 316 horizontally neighboring one another in the Y-direction.

A dielectric liner material 328 may be formed over the digit line structures 326 of the memory array structure 102. For instance, the dielectric liner material 328 may be formed (e.g., conformally deposited) over the digit line structures 326.

The dielectric liner material 328 may be formed of and include insulative material. In some embodiments, the dielectric liner material 328 is formed of and includes silicon dioxide. The third dielectric liner material 328 may have a thickness within a range of from about 3 nm to about 7 nm (e.g., about 5 nm).

A shield structure 330 may be formed over the dielectric liner material 328. For instance, the shield structure 330 may be deposited (e.g., conformally deposited) over the dielectric liner material 328 and within recesses horizontally between neighboring digit line structures 326. The shield structure 330 may at least substantially entirely fill the recesses and cover an upper surface of the dielectric liner material 328. As a result, in some embodiments, the shield structure 330 includes projections 332 extending vertically downward between horizontally neighboring digit line structures 326. Moreover, because the shield structure 330 at least substantially entirely fills the recesses horizontally between neighboring digit line structures 326, the shield structure 330 may extend vertically in-between neighboring digit line structures 326. Put another way, portions of the shield structure 330 may be horizontally interposed between neighboring digit line structures 326 of the memory array structure 102.

The shield structure 330 (e.g., upper shielding plate, top shielding plate) may be configured and positioned to shield (e.g., protect) features (e.g., structures, materials, devices, digit lines) within the memory cells 324 of the memory array structure 102 from undesirable electrical interference (e.g., electromagnetic interference (EMI)).

In some embodiments, the dielectric liner material 328 at least substantially fills recesses horizontally between neighboring digit line structures 326, and the shield structure 330 may be formed over a substantially uniform or continuous upper surface of the dielectric liner material 328. As a result, in some embodiments, the shield structure 330 does not include the projections 332 extending vertically downward between horizontally neighboring digit line structures 326 and, rather, includes a generally flat structure.

Referring still to FIG. 3, the shield structure 330 may vertically overlie the digit line structures 326, which vertically overlie the access devices 314 of the memory cells 324. Accordingly, the access devices 314 may be vertically interposed between the digit line structures 326 and the multi-storage node structure 310.

The shield structure 330 may be formed of and include conductive material. In some embodiments, the shield structure 330 is formed of and includes metallic material, such as one or more of at least one metal, at least one alloy, and at least one conductive metal-containing material (e.g., a conductive metal nitride, a conductive metal silicide, a conductive metal carbide, a conductive metal oxide). By way of non-limiting example, the shield structure 330 may be formed of and include tungsten (W). The shield structure 330 may be substantially homogeneous, or the shield structure 330 may be heterogeneous. If the shield structure 330 is heterogeneous, amounts of one or more elements included in the shield structure 330 may vary stepwise (e.g., change abruptly), or may vary continuously (e.g., change progressively, such as linearly, parabolically) throughout different portions of the shield structure 330. The shield structure 330 may, for example, be formed of and include a stack of at least two different conductive materials.

The memory array structure 102 may also include first interconnect structures 334 and at least one first routing tier 336 including first routing structures 338. The individual first interconnect structures 334 may be formed to contact (e.g., physically contact, electrically contact) one of the word line structures 318, one of the digit line structures 326, or the shared carrier 308 (described below). The first interconnect structures 334 may respectively be formed of and include conductive material. In some embodiments, the first interconnect structures 334 are individually formed of and include one or more of W, Cu, Al, Ru, Mo, and TiN_{y}.

The first routing structures 338 may be formed to vertically overlie the first interconnect structures 334. Some of the first routing structures 338 may be coupled to (e.g., in physical contact, electrical contact with) the first interconnect structures 334 (and, hence, the word line structures 318, the digit line structures 326, or the shared carrier 308). The first routing structures 338 may respectively be formed of and include conductive material. In some embodiments, the first routing structures 338 are individually formed of and include one or more of W, Cu, Al, Ru, Mo, and TiN_{y}.

Additionally, shield contacts 340 may be formed to contact (e.g., physically contact, electrically contact) the shield structure 330. The shield contacts 340 may respectively be formed of and include conductive material. In some embodiments, the shield contacts 340 are individually formed of and include one or more of W, Cu, Al, Ru, Mo, and TiN_{y}. Additionally, the shield contacts 340 may extend vertically to one or more of the first routing structures 338. As a result, the shield contacts 340 may reach the shield structure 330 from a side of the shield structure 330 opposite the access devices 314 and the multi-storage node structures 310 of the memory array structure 102 (e.g., from a top of the shield structure 330). In some embodiments, the shield contacts 340 are utilized to apply a voltage bias to the shield structure 330 to control or enhance protection provided by the shield structure 330 from undesirable electrical interference (e.g., electromagnetic interference (EMI)).

The memory array structure 102 may further include at least one second routing tier 342 including second routing structures 302 and second interconnect structures 344. In particular, the second routing structures 302 may be formed vertically overlying the first routing structures 338. Some of the second routing structures 302 may be coupled to the second interconnect structures 344 (and, hence, the digit line structures 326, the word line structures 318, or the shared carrier 308). The second routing structures 302 may respectively be formed of and include conductive material. In some embodiments, the second routing structures 302 are individually formed of and include one or more of W, Ru, Mo, and TiN_{y}.

The individual second interconnect structures 344 may be formed to contact (e.g., physically contact, electrically contact) and extend vertically between the first routing structures 338 and the second routing structures 302. For example, the second interconnect structures 344 may be formed to couple at least one of the second routing structures 302 to at least some of the first routing structures 338. The second interconnect structures 344 may respectively be formed of and include conductive material. In some embodiments, the second interconnect structures 344 are individually formed of and include one or more of W, Cu, Al, Ru, Mo, and TiN_{y}.

Referring still to FIG. 3, a first insulative material 346 may be formed on or over portions of at least the shared carrier 308, the multi-storage node structure 310, the memory array structure 102, the first interconnect structures 334, the first routing structures 338, the second routing structures 302, and the second interconnect structures 344. In some embodiments, the first insulative material 346 is formed of and includes a dielectric oxide material, such as SiOx (e.g., SiO₂). The first insulative material 346 may be substantially homogeneous, or the first insulative material 346 may be heterogeneous. An upper surface of the first insulative material 346 may be formed to be substantially planar. In some embodiments, the upper surface of the first insulative material 346 is formed to vertically overlie the upper surfaces of the uppermost ones of the second routing structures 302. In additional embodiments, the upper surface of the first insulative material 346 is formed to be substantially coplanar with upper surfaces of uppermost ones of the second routing structures 302.

As is discussed in greater detail below, the first insulative material 346 may be utilized to bond the memory array structure 102 to the control circuitry structure 104 through a dielectric-to-dielectric bond, such as an oxide-to-oxide bond.

As noted above, within a patch region of a bank region of the microelectronic device 100, the first memory assembly 304 and the second memory assembly 306 may be overlying the shared carrier 308. In some embodiments, the shared carrier 308 includes a semiconductor material 348 (e.g., one or more of a silicon material, such monocrystalline silicon or polycrystalline silicon (also referred to herein as “polysilicon”); silicon-germanium; germanium; gallium arsenide; a gallium nitride; gallium phosphide; indium phosphide; indium gallium nitride; and aluminum gallium nitride) overlying a cell plate 350. The cell plate 350 may include a conductive material (e.g., tungsten). Additionally, in some embodiments, the cell plate 350 of the shared carrier 308 forms an electrode of a common cell multi-capacitor structure (e.g., common structure of metal-insulator-metal (MIM) capacitors, common structure of metal-insulator-semiconductor (MIS) capacitors). The cell plate 350 may overlie a first dielectric structure 352. The first dielectric structure 352 may include any of the dielectric and/or insulative materials described herein.

Referring to FIG. 3 and FIG. 4 together, the first dielectric structure 352 may overlie a second dielectric structure 354 overlying a base structure 356. The second dielectric structure 354 may include any of the dielectric and/or insulative materials described herein. In some embodiments, the second dielectric structure 354 includes a same material as the first dielectric structure 352. As is discussed in greater detail below, thicknesses of the first dielectric structure 352 and the second dielectric structure 354 may be selected to achieve a desired minimum distance (T) between the cell plate 350 and the base structure 356 (e.g., carrier wafer) in the Z-direction.

The base structure 356 may include a base material or construction upon which additional features (e.g., materials, structures, devices) of the formed. In some embodiments, the base structure 356 includes a wafer. The base structure 356 may be formed of and include one or more of semiconductor material (e.g., one or more of a silicon material, such monocrystalline silicon or polycrystalline silicon (also referred to herein as “polysilicon”); silicon-germanium; germanium; gallium arsenide; a gallium nitride; gallium phosphide; indium phosphide; indium gallium nitride; and aluminum gallium nitride), a base semiconductor material on a supporting structure, glass material (e.g., one or more of BSP, PSG, FSG, BPSG, aluminosilicate glass, an alkaline earth boro-aluminosilicate glass, quartz, titania silicate glass, and soda-lime glass), and ceramic material (e.g., one or more of p-AlN, SOPAN, AlN, aluminum oxide (e.g., sapphire; α-Al₂O₃), and silicon carbide). By way of non-limiting example, the base structure 356 may comprise a semiconductor wafer (e.g., a silicon wafer), a glass wafer, or a ceramic wafer. The base structure 356 may include one or more layers, structures, and/or regions formed therein and/or thereon.

In one or more embodiments, the cell plate 350 and the associated cell capacitor structure are utilized to regulate voltages supplied to one or more of charge pumps (e.g., V_{CCP} charge pumps, V_{NEGWL} charge pumps, DVC2 charge pumps), delay-locked loop (DLL) circuitry (e.g., ring oscillators), V_{dd} regulators, drivers (e.g., main word line drivers, sub word line drivers (SWD)), page buffers, decoders (e.g., local deck decoders, column decoders, row decoders), sense amplifiers (e.g., equalization (EQ) amplifiers, isolation (ISO) amplifiers, NMOS sense amplifiers (NSAs), PMOS sense amplifiers (PSAs)), repair circuitry (e.g., column repair circuitry, row repair circuitry), I/O devices (e.g., local I/O devices), memory test devices, array multiplexers (MUX), error checking and correction (ECC) devices, self-refresh/wear leveling devices, and other chip/deck control circuitry. For instance, the cell plate 350 may support and/or form a portion of so called “decoupling capacitors” and/or “pump capacitors.”

Referring still to FIG. 3 and FIG. 4 together, in some embodiments, the cell plate 350 is continuous between the first memory assembly 304 and the second memory assembly 306 (e.g., tiles, patches, subarrays).

During formation of the microelectronic device 100, the base structure 356 (e.g., carrier wafer) and the second dielectric structure 354 may be attached to the cell plate 350 and the first dielectric structure 352 by way of one or more oxide-to-oxide bonds, depicted in FIG. 4 by dashed line 358. In particular, to attach the base structure 356 and the second dielectric structure 354 to the cell plate 350 and the first dielectric structure 352, the second dielectric structure 354 may be provided in physical contact with at least the first dielectric structure 352, and the second dielectric structure 354 and the first dielectric structure 352 may be exposed to annealing conditions to form bonds (e.g., oxide-to-oxide bonds) between the second dielectric structure 354 and the first dielectric structure 352. By way of non-limiting example, the second dielectric structure 354 and the first dielectric structure 352 may be exposed to a temperature greater than or equal to about 400° C. (e.g., within a range of from about 300° C. to about 500° C., greater than about 500°°C.) to form oxide-to-oxide bonds between the second dielectric structure 354 and the first dielectric structure 352. In some embodiments, the second dielectric structure 354 and the first dielectric structure 352 are exposed to at least one temperature greater than about 800° C. to form oxide-to-oxide bonds between the second dielectric structure 354 and the first dielectric structure 352.

As noted above, in some embodiments, thicknesses of the first dielectric structure 352 and the second dielectric structure 354 are selected to achieve a desired minimum distance (T) between the cell plate 350 and the base structure 356 (e.g., carrier wafer) in the Z-direction. In some embodiments, a thickness of the first dielectric structure 352 underlying or overlying, depending on a given orientation, lowermost portions of the cell plate 350 in the Z-direction and a thickness of the second dielectric structure 354 overlying the base structure 356 are selected prior to attachment of the base structure 356 to the cell plate 350 and memory array structure 102. To facilitate description of embodiments herein, a portion of the first dielectric structure 352 below a lowermost elevation of the cell plate 350 and the second dielectric structure 354 overlying the base structure 356 may be referred to herein collectively as an isolation oxide structure 360. In some embodiments, thicknesses of the first dielectric structure 352 and the second dielectric structure 354 are selected to achieve a minimum distance (T) between the cell plate 350 and the base structure 356 and a thickness of the isolation oxide structure 360 within a range of about 1000 nm to about 10000 nm. As a non-limiting example, thicknesses of the first dielectric structure 352 and the second dielectric structure 354 may be selected to achieve a minimum distance (T) and a thickness of the isolation oxide structure 360 of about 1200 nm. As a result, a minimum distance (T) between the cell plate 350 and the base structure 356 may be within a range of about 1000 nm to about 10000 nm.

In some embodiments, thicknesses of the first dielectric structure 352 and the second dielectric structure 354 are selected (e.g., achieved) by depositing one or more dielectric materials on the cell plate 350 and the base structure 356 and then removing any undesired material by way of any of the removal processes described herein (e.g., a CMP process) prior to attaching the base structure 356 to the cell plate 350.

Forming the first dielectric structure 352 and the second dielectric structure 354 to form an isolation oxide structure 360 having a thickness in the Z-direction within a range of about 1000 nm and about 10000 nm increases a capacitance between the base structure 356 and the cell plate 350 and mitigates a risk of unintentional electrostatic discharge between the cell plate 350 and the base structure 356. Accordingly, the isolation oxide structure 360 described herein can mitigate the risks of gate oxide breakdown, damage to p-n junctions, data corruption, latch-up conditions, functional interruptions, and leakage currents often associated with electrostatic discharge. As a result, the isolation oxide structure 360 described herein can improve reliability of microelectronic devices in comparison to conventional devices.

As described briefly above, each of the first memory assembly 304 and the second memory assembly 306 includes a control circuitry structure 104. The control circuitry structure 104 may be formed separately from memory array structure 102 and may configured to be attached (e.g., bonded) to the memory array structure 102, as described in further detail below.

The control circuitry structure 104 may include a second base structure 362 including a second semiconductor material 364 and isolation structures 366 (e.g., shallow trench isolation (STI) structures) vertically extending at least partially through the second semiconductor material 364 of the second base structure 362.

The second base structure 362 may include a base material or construction upon which additional features (e.g., materials, structures, devices) of the control circuitry structure 104 may be formed. The second base structure 362 may include a semiconductor structure (e.g., a semiconductor wafer), or a base semiconductor material (e.g., the second semiconductor material 364) on a supporting structure. For example, the second base structure 362 may include a conventional silicon substrate (e.g., a conventional silicon wafer), or another bulk substrate including a semiconductor material. In some embodiments, the second base structure 362 includes a silicon wafer. The second base structure 362 may include one or more other layers, structures, and/or regions formed therein and/or thereon. The second semiconductor material 364 of the second base structure 362 may include any of the semiconductor materials described herein.

The isolation structures 366 may include trenches (e.g., openings, vias, apertures) within at least the second semiconductor material 364 of the second base structure 362 filled with insulative material, such as one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, and TiOₓ), at least one dielectric nitride material (e.g., SiN_{y}), at least one dielectric oxynitride material (e.g., SiOₓN_{y}), at least one dielectric carboxynitride material (e.g., SiOₓC_{z}N_{y}), and amorphous carbon. In some embodiments, the further isolation structures 366 are respectively formed of and include SiOₓ (e.g., SiO₂).

As noted briefly above, the isolation structures 366 may, for example, be employed as STI structures within the second base structure 362. The isolation structures 366 may be formed to vertically extend partially (e.g., less than completely) through the second base structure 362. In some embodiments, a vertical depth (e.g., vertical height) of the isolation structures 366 is within a range of from about 200 nanometers (nm) to about 2000 nm. Each of the isolation structures 366 may be formed to exhibit substantially the same dimensions and shape as each other of the isolation structures 366, or at least one of the isolation structures 366 may be formed to exhibit one or more of different dimensions and a different shape than at least one other of the isolation structures 366. As a non-limiting example, each of the isolation structures 366 may be formed to exhibit substantially the same vertical dimension(s) and substantially the same vertical cross-sectional shape(s) as each other of the isolation structures 366; or at least one of the isolation structures 366 may be formed to exhibit one or more of different vertical dimension(s) and different vertical cross-sectional shape(s) than at least one other of the isolation structures 366. In some embodiments, the isolation structures 366 are all formed to vertically extend to and terminate at substantially the same depth within the second base structure 362. In additional embodiments, at least one of the isolation structures 366 is formed to vertically extend to and terminate at a relatively deeper depth within the second base structure 362 than at least one other of the isolation structures 366. As another non-limiting example, each of the isolation structures 366 may be formed to exhibit substantially the same horizontal dimension(s) and substantially the same horizontal cross-sectional shape(s) as each other of the isolation structures 366; or at least one of the isolation structures 366 may be formed to exhibit one or more of different horizontal dimension(s) (e.g., relatively larger horizontal dimension(s), relatively smaller horizontal dimension(s)) and different horizontal cross-sectional shape(s) than at least one other of the isolation structures 366. In some embodiments, at least one of the isolation structures 366 is formed to have one or more different horizontal dimensions (e.g., in the X-direction and/or in the Y-direction) than at least one other of isolation structures 366.

The control circuitry structure 104 may further include transistors 368. The transistors 368 may individually include conductively doped regions 502 (e.g., source/drain regions), a channel region 504, a gate structure 506 (e.g., a gate electrode), and a gate dielectric material 508. For an individual transistor 368, the conductively doped regions 502 thereof may be formed within the second semiconductor material 364 of the second base structure 362; the channel region 504 thereof may be formed within the second semiconductor material 364 of the second base structure 362 and may be horizontally interposed between the conductively doped regions 502 of the individual transistor 368; the gate structure 506 may vertically overlie and horizontally overlap the channel region 504 of the individual transistor 368; and the gate dielectric material 508 (e.g., dielectric oxide material) may be vertically interposed (e.g., in the Z-direction) between the gate structure 506 and the channel region 504.

For an individual transistor 368, the conductively doped regions 502 thereof may include the second semiconductor material 364 of the second base structure 362 doped with one or more desired conductivity-enhancing dopants. In some embodiments, the conductively doped regions 502 of the transistor 368 includes the second semiconductor material 364 doped with at least one N-type dopant (e.g., one or more of phosphorus, arsenic, antimony, and bismuth). In some of such embodiments, the channel region 504 of the transistor 368 includes the second semiconductor material 364 doped with at least one P-type dopant (e.g., one or more of boron, aluminum, and gallium). In some other of such embodiments, the channel region 504 of the transistor 368 includes substantially undoped second semiconductor material 364. In additional embodiments, for an individual transistor 368, the conductively doped regions 502 include the second semiconductor material 364 doped with at least one P-type dopant (e.g., one or more of boron, aluminum, and gallium). In some of such additional embodiments, the channel region 504 of the transistor 368 includes the second semiconductor material 364 doped with at least one N-type dopant (e.g., one or more of phosphorus, arsenic, antimony, and bismuth). In some other of such additional embodiments, the channel region 504 of the transistor 368 includes substantially undoped second semiconductor material 364.

The gate structures 506 (e.g., gate electrodes, gates) may individually horizontally extend between and be employed by multiple transistors 368. The gate structures 506 may be formed of and include conductive material. The gate structures 506 may individually be substantially homogeneous, or the gate structures 506 may individually be heterogeneous. In some embodiments, the gate structures 506 are each substantially homogeneous. In additional embodiments, the gate structures 506 are each heterogeneous. Individual gate structures 506 may, for example, be formed of and include a stack of at least two different conductive materials.

The control circuitry structure 104 may further include a dielectric capping structures 510 form on upper surfaces of the gate structures 506, and dielectric spacer structures 512 on side surfaces of (e.g., horizontally bookending) the gate structures 506, the gate dielectric material 508, and the dielectric capping structures 510.

In addition, the control circuitry structure 104 further includes third interconnect structures 514 vertically overlying and in contact (e.g., physical contact, electrical contact) with the conductively doped regions 502 of the transistors 368. In some embodiments, the third interconnect structures 514 vertically overlie, horizontally overlap, and physically contact the conductively doped regions 502 of the transistors 368. The third interconnect structures 514 may individually be formed of and include conductive material. In some embodiments, the third interconnect structures 514 are individually formed of and include one or more of W, Ru, Mo, and TiN_{y}.

In some embodiments, the control circuitry structure 104 further includes third routing structures 370 vertically overlying the transistors 368. As shown in FIG. 5, some of the third routing structures 370 may be coupled to the third interconnect structures 514 (and, hence, the transistors 368). The third routing structures 370 may respectively be formed of and include conductive material. In some embodiments, the third routing structures 370 are individually formed of and include one or more of W, Ru, Mo, and TiN_{y}.

The transistors 368, the third interconnect structures 514, and at least some of the third routing structures 370 may form control logic circuitry of various control logic devices 516 configured to control various operations of various features (e.g., the memory cells 324) of the microelectronic device 100 (e.g., a memory device, such as a DRAM device). In some embodiments, the control logic devices 516 include complementary metal-oxide-semiconductor (CMOS) circuitry. As a non-limiting example, the control logic devices 516 may include one or more (e.g., each) of charge pumps (e.g., V_{CCP} charge pumps, V_{NEGWL} charge pumps, DVC2 charge pumps), delay-locked loop (DLL) circuitry (e.g., ring oscillators), V_{dd} regulators, drivers (e.g., main word line drivers, sub word line drivers (SWD)), page buffers, decoders (e.g., local deck decoders, column decoders, row decoders), sense amplifiers (e.g., equalization (EQ) amplifiers, isolation (ISO) amplifiers, NMOS sense amplifiers (NSAs), PMOS sense amplifiers (PSAs)), repair circuitry (e.g., column repair circuitry, row repair circuitry), I/O devices (e.g., local I/O devices), memory test devices, array multiplexers (MUX), error checking and correction (ECC) devices, self-refresh/wear leveling devices, and other chip/deck control circuitry. Different regions of the control circuitry structure 104 may have different control logic devices 516 formed within horizontal areas thereof.

Referring to FIG. 3 through FIG. 5 together, the memory array structure 102 and the control circuitry structure 104 may include fourth interconnect structures 372 vertically extending from some of the third routing structures 370, through the at least some of the isolation structures 366 of the control circuitry structure 104, and to at least some of the second routing structures 302 of the memory array structure 102. During formation of the microelectronic device 100, the fourth interconnect structures 372 may be formed subsequent to the control circuitry structure 104 being attached to the memory array structure 102 by way of one or more bonds (e.g., oxide-to-oxide bonds) (described below).

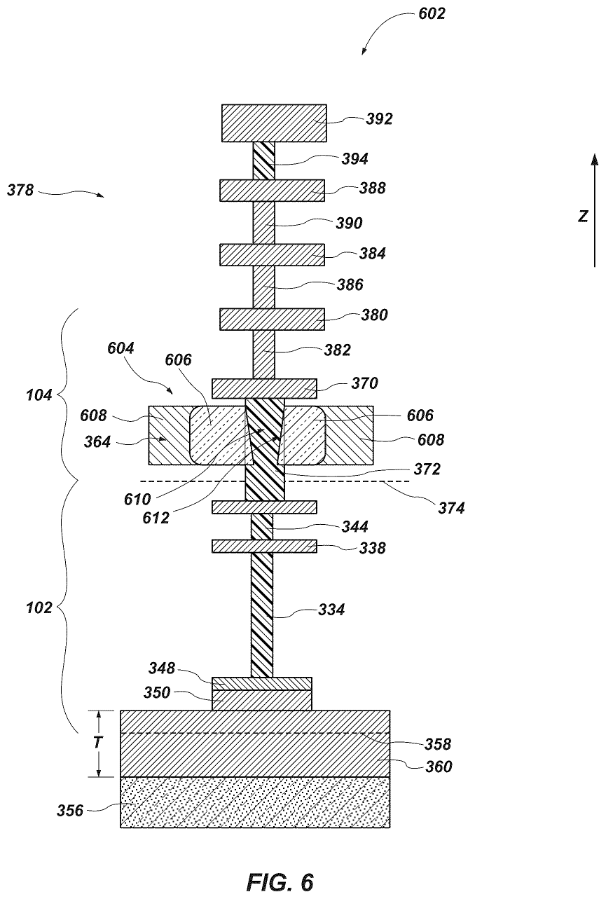

Some of the fourth interconnect structures 372 may be formed to vertically extend from some of the third routing structures 370 vertically overlying the control logic devices 516 to some of the second routing structures 302 and, as a result, the first routing structures 338, vertically underlying the control logic devices 516. One or more (e.g., each) of the fourth interconnect structures 372 may be formed to horizontally overlap and vertically extend through one or more of the isolation structures 366 (e.g., STI structures) of the control circuitry structure 104. Optionally, one or more other of the fourth interconnect structures 372 may be formed to horizontally overlap and vertically extend through the second semiconductor material 364 of the control circuitry structure 104. Moreover, as is described in further detail below in regard to FIG. 6, one or more of the fourth interconnect structures may be formed to horizontally overlap and vertically extend through antenna diode structures formed in the second semiconductor material 364 of the control circuitry structure 104.

The fourth interconnect structures 372 may facilitate (in combination with at least the third routing structures 370, the third interconnect structures 514, the second routing structures 302, the second interconnect structures 344, the first routing structures 338, the first interconnect structures 334, the RDM structures 320, the digit line structures 326, and the word line structures 318) operable communication between the control logic devices 516 and each of the memory cells 324 vertically thereunder. The fourth interconnect structures 372 may be formed of and include conductive material. In some embodiments, the fourth interconnect structures 372 are individually formed of and include one or more of W, Ru, Mo, and TiN_{y}.

Referring again to FIG. 3, as noted briefly above, the control circuitry structure 104 may be attached to the memory array structure 102 by way of one or more bonds (e.g., oxide-to-oxide bonds), depicted in FIG. 3 by dashed line 374. In particular, a second insulative material 376 of the control circuitry structure 104 underlying the second base structure 362 may be put in physical contact with the first insulative material 346 of the memory array structure 102, and then the second insulative material 376 and the first insulative material 346 may be exposed to annealing conditions to form bonds (e.g., dielectric-to-dielectric bonds, such as oxide-to-oxide bonds) between the second insulative material 376 and the first insulative material 346. By way of non-limiting example, the second insulative material 376 and the first insulative material 346 may be exposed to a temperature greater than or equal to about 400° C. (e.g., within a range of from about 400° C. to about 800° C., greater than about 800° C.) to form bonds between the second insulative material 376 and the first insulative material 346. While FIG. 3 includes the dashed line 374 representing an initial interface location between the memory array structure 102 and the control circuitry structure 104 before the bonding process, the second insulative material 376 and the first insulative material 346 may be integral and continuous with one another following the bonding process. The control circuitry structure 104 may be attached to the memory array structure 102 without a bond line.

Referring to FIG. 3 through FIG. 5 again, in view of the foregoing, the control circuitry structure 104 may be attached to a side of the memory array structure 102 vertically closer to the access devices 314 of the memory cells 324 than the storage node devices 322 of the memory cells 324. Put another way, the control circuitry structure 104 may be attached to a side of the memory array structure 102 opposite the multi-storage node structure 310. Furthermore, the shield structure 330 and digit line structures 326 may be vertically interposed between the control circuitry structure 104 and the memory cells 324, the access devices 314 may be vertically interposed between the multi-storage node structure 310 and the control circuitry structure 104, and the access devices 314 may be vertically interposed between the multi-storage node structure 310 and the shield structure 330 and digit line structures 326.

Additionally, referring specifically to FIG. 3 and FIG. 5, back-end-of-line (BEOL) structures 378 may be formed vertically over the third routing structures 370. The BEOL structures 378 may include fourth routing structures 380 formed vertically over the control logic devices 516. In addition, fifth interconnect structures 382 may be formed to couple at least some of the fourth routing structures 380 to at least some of the control logic devices 516, and fifth interconnect structures 382 may be formed to couple at least some of the fourth routing structures 380 to at least some of the third routing structures 370. The fifth interconnect structures 382 and the fourth routing structures 380 may respectively be formed of and include conductive material. In some embodiments, the fourth interconnect structures 372 and the fourth routing structures 380 are individually formed of and include one or more of W, Ru, Mo, and TiN_{y}.

Furthermore, the BEOL structures 378 may include fifth routing structures 384 formed vertically over the fourth routing structures 380. In addition, sixth interconnect structures 386 may be formed to couple at least some of the fifth routing structures 384 to at least some of the fourth routing structures 380. The sixth interconnect structures 386 and the fifth routing structures 384 may respectively be formed of and include conductive material. In some embodiments, the sixth interconnect structures 386 and the fifth routing structures 384 are individually formed of and include one or more of W, Ru, Mo, and TiN_{y}.

Likewise, the BEOL structures 378 may include sixth routing structures 388 formed vertically over the fifth routing structures 384. In addition, seventh interconnect structures 390 may be formed to couple at least some of the sixth routing structures 388 to at least some of the fifth routing structures 384. The seventh interconnect structures 390 and the sixth routing structures 388 may respectively be formed of and include conductive material. In some embodiments, the seventh interconnect structures 390 and the sixth routing structures 388 are individually formed of and include one or more of W, Ru, Mo, and TiN_{y}.

Moreover, additional BEOL structures 378 may be formed vertically over the sixth routing structures 388. For example, at least one additional routing tier (e.g., at least two additional routing tiers) including additional routing structures may be formed over the sixth routing structures 388; and pad structures 392 may be formed over the additional routing structures. In addition, additional contact structures may be formed to couple different additional routing structures with one another, different sixth routing structures 388, and/or different pad structures 392, as desired. Some of the additional routing structures may be coupled to some of the sixth routing structures 388 by way of some of the additional interconnect structures. For example, the BEOL structures 378 may include eighth interconnect structures 394, which may couple at least some of the sixth routing structures 388 to the pad structures 392. Some of the additional routing structures may be coupled to some other of the additional routing structures by way of some other of the additional interconnect structures, and some of the additional routing structures may be coupled to some of the pad structures 392 by way of yet still other of the additional interconnect structures. The additional routing structures, the pad structures 392, the eighth interconnect structures 394, and the additional interconnect structures may respectively be formed of and include conductive material. In some embodiments, the additional routing structures, the pad structures 392, the eighth interconnect structures 394, and the additional contact structures are individually formed of and include one or more of W, Cu, Al, Ru, Mo, and TiN_{y}.

In some embodiments, the BEOL structures 378 also include one or more multi-capacitor structures 518. The multi-capacitor structure 518 may include, for example, a structure of metal-insulator-metal (MIM) capacitors or a structure of metal-insulator-semiconductor (MIS) capacitors. Each of the capacitors of the multi-capacitor structures 518 may, for example, be formed to include a first electrode (e.g., a bottom electrode), a second electrode (e.g., a top electrode), and a first dielectric material between the first electrode and the second electrode.

A third insulative material 520 may be formed on or over portions of at least the second base structure 362, the transistors 368, the third routing structures 370, the fifth interconnect structures 382, the control logic devices 516, the fourth routing structures 380, the sixth interconnect structures 386, the fifth routing structures 384, the seventh interconnect structures 390, the sixth routing structures 388, the BEOL structures 378. In some embodiments, the third insulative material 520 is formed of and includes a dielectric oxide material, such as SiOx (e.g., SiO₂). The third insulative material 520 may be substantially homogeneous, or the third insulative material 520 may be heterogeneous. An upper surface of the third insulative material 520 may be formed to be substantially planar. In some embodiments, the upper surface of the third insulative material 520 is formed vertically overlie the upper surfaces of the pad structures 392. In additional embodiments, the upper surface of the third insulative material 520 is formed to be substantially coplanar with upper surfaces of the pad structures 392.

Referring still to FIG. 3 through FIG. 5, in one or more embodiments, one or more of the BEOL structures 378, the fourth interconnect structures 372, the fifth interconnect structures 382, the fourth routing structures 380, the sixth interconnect structures 386, the fifth routing structures 384, the seventh interconnect structures 390, or the sixth routing structures 388 are formed subsequent to the control circuitry structure 104 being attached to the memory array structures 102.

Referring again to FIG. 3, the microelectronic device 100 may include contact assemblies 396 operably coupled to the cell plate 350. The contact assemblies 396 may be formed at or proximate horizontal edges of a group (e.g., array) of memory assemblies (e.g., the first memory assembly 304 and the second memory assembly 306) (e.g., at an edge of array (EOA)). In other words, the contact assemblies 396 coupled to the cell plate 350 may be formed proximate horizontal perimeters of the patch regions or bank regions of the microelectronic device 100.

In some embodiments, the contact assemblies 396 include one or more structures of the memory array structures 102 and control circuitry structure 104 (e.g., existing structures). For instance, the contact assemblies 396 may include one or more of the first interconnect structures 334, the first routing structures 338, the second interconnect structures 344, the RDM structures 320 of the RDL tier 312, the second routing structures 302, the fourth interconnect structures 372, the third routing structures 370, the fifth interconnect structures 382, the fourth routing structures 380, the sixth interconnect structures 386, the fifth routing structures 384, the seventh interconnect structures 390, the sixth routing structures 388, the BEOL structures 378, the eighth interconnect structures 394, or the pad structures 392.

FIG. 6 is a simplified, partial plan view of a contact assembly 602 that may be implemented into the microelectronic device 100 of FIG. 3 through FIG. 5 according to one or more embodiments. The contact assembly 602 may include one or more structures of the memory array structures 102 and control circuitry structure 104 (e.g., existing structures). For instance, the contact assembly 602 may include one or more of the first interconnect structures 334, the first routing structures 338, the second interconnect structures 344, the RDM structures 320 of the RDL tier 312, the second routing structures 302, the fourth interconnect structures 372, the third routing structures 370, the fifth interconnect structures 382, the fourth routing structures 380, the sixth interconnect structures 386, the fifth routing structures 384, the seventh interconnect structures 390, the sixth routing structures 388, the BEOL structures 378, the eighth interconnect structures 394, or the pad structures 392.

The contact assembly 602 may further include an antenna diode structure 604 for mitigating risk of unintentional electrostatic discharges within the microelectronic device 100 (FIG. 3). The antenna diode structure 604 may be formed within the control circuitry structure 104 of the microelectronic device 100 (FIG. 3) and may include a first doped region 606 of the second semiconductor material 364 and a second doped region 608 of the second semiconductor material 364. Within the second semiconductor material 364, the first doped region 606 may be horizontally flanked by portions of the second doped region 608. In particular, the first doped region 606 may be formed between two opposing portions of the second doped region 608. Accordingly, the second doped region 608 of the second semiconductor material 364 may at least partially surround outer lateral (e.g., horizontal) boundaries of the first doped region 606 and may horizontally neighbor the first doped region 606.

In some embodiments, one of the first doped region 606 and the second doped region 608 is N-type doped, such as N-type doped to an N-type dopant concentration within a range of from about 10¹⁵ cm⁻³ to about 10²⁰ cm⁻³, while the other of the first doped region 606 and the second doped region 608 is P-type doped, such as P-type doped to a P-type dopant concentration within a range of from about −10¹³ cm⁻³ to about −10¹⁸ cm⁻³. In additional embodiments, one or more of the first doped region 606 and the second doped region 608 is doped (either P-doped or N-doped) to the point of saturation (e.g., greater than or equal to about −10¹⁸ cm⁻³). The doping may be accomplished utilizing any suitable processing, such as by implanting dopant (e.g., at least one N-type dopant or at least one P-type dopant) into the second semiconductor material 364 of the second base structure 362. A P-type dopant may include one or more of boron, aluminum, and gallium; and an N-type dopant may include one or more of arsenic, phosphorous, antimony, and bismuth.

The antenna diode structure 604 may further include a trench 610 (e.g., opening, via, aperture) formed within the first doped region 606 of the second semiconductor material 364, and the first doped region 606 may at least substantially define a lateral sidewall 612 or lateral sidewalls 612 of the trench 610. In other words, the trench 610 may be formed vertically through the first doped region 606 of the second semiconductor material 364 such that the first doped region 606 defines the lateral boundaries (i.e., lateral sidewalls 612) of the trench 610. In view of the foregoing, because the first doped region 606 is doped with one of an N-dopant or a P-dopant, and the second doped region 608 is doped with the other of an N-dopant or a P-dopant, the first doped region 606 and the second doped region 608 form a PN junction which allows current to flow in one direction but not the other direction.

Referring still to FIG. 6, a fourth interconnect structure 372 of the contact assembly 602 may be formed to horizontally overlap and vertically extend through the trench 610 formed through the first doped region 606 of the second semiconductor material 364. Furthermore, the fourth interconnect structure 372 of the contact assembly 602 may be formed to contact at least one lateral sidewall 612 of the first doped region 606 of the second semiconductor material 364 defining the trench 610. Moreover, the fourth interconnect structure 372 vertically overlaps with both of at least a portion the memory array structure 102 and at least a portion of the control circuitry structure 104.

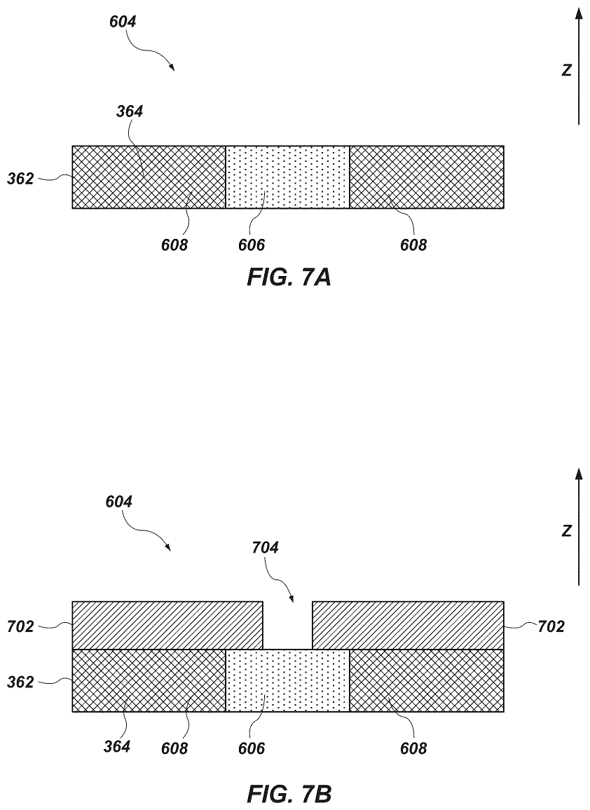

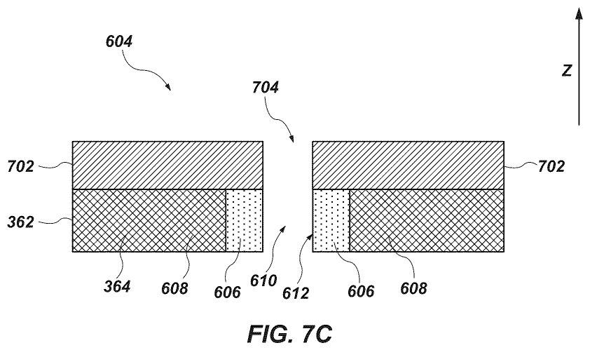

The antenna diode structure 604 (i.e., the first doped region 606 of the second semiconductor material 364, the second doped region 608 of the second semiconductor material 364, and the trench 610) may be formed during formation of the control circuitry structure 104 and prior to the control circuitry structure 104 being bonded to the memory array structure 102. Furthermore, as noted above, the fourth interconnect structure 372 may be formed subsequent to the control circuitry structure 104 being bonded to the memory array structure 102. Formation of the antenna diode structure 604 is described below in regard to FIG. 7A through FIG. 7C.

As noted above, the antenna diode structure 604 mitigates a risk of unintentional electrostatic discharge within the microelectronic device 100. For example, due to the PN junction formed by the antenna diode structure 604, which permits current to flow in a single direction, the antenna diode structure 604 may act as an antenna and a release of static electricity that builds up within the microelectronic device 100. In particular, the antenna diode structure 604 may attract and collect electrostatic charge that builds up within the microelectronic device 100, and the PN junction provides a one-way controlled path for a discharge. In other words, the antenna diode structure 604 provides a path for the static electricity to safely dissipate without damaging the microelectronic device 100. Accordingly, the antenna diode structure 604 described herein can mitigate the risks of gate oxide breakdown, damage to p-n junctions, data corruption, latch-up conditions, functional interruptions, and leakage currents often associated with electrostatic discharge. As a result, the antenna diode structures 604 described herein can improve reliability of microelectronic devices in comparison to conventional devices.

Referring still to FIG. 6, the contact assembly 396 may be coupled to the cell plate 350. Furthermore, in some embodiments, the microelectronic device 100 (FIG. 3) includes the isolation oxide structure 360 formed from the first dielectric structure 352 (FIG. 3) and the second dielectric structure 354 (FIG. 3) described above in regard to FIG. 3. The isolation structure 366 may horizontally overlap with the contact assembly 396 and be vertically interposed between the cell plate 350 and the base structure 356. In particular, a portion of the cell plate 350 to which the contact assembly 396 is coupled may be separated from the base structure 356 in the Z-direction by any of the distances (T) described above in regard to FIG. 3. Furthermore, the isolation structure 366 and the separation of the cell plate 350 from the base structure 356 may provide any of the advantages regarding mitigating a risk of unintentional electrostatic discharge within the microelectronic device 100. In view of the foregoing, in some embodiments, a microelectronic device 100 includes both one or more antenna diode structures 604 and the isolation structure 366 interposed between the cell plate 350 and the base structure 356 at a location horizontally overlapping with a given contact assembly 396.

FIG. 7A through FIG. 7C include simplified, vertical cross-sectional views of an antenna diode structure 604 at different processing stages of a method of forming the antenna diode structure 604, according to one or more embodiments of the disclosure.

Referring to FIG. 7A, during formation of the control circuitry structure 104, the second base structure 362 may be formed to include the first doped region 606 and the second doped region 608 in a portion of the base structure 356 intended to horizontally align with the contact assembly 396 (FIG. 3). The first doped region 606 and the second doped region 608 may include any of the dopant combinations described above in regard to FIG. 6. The doping may be accomplished utilizing any suitable processing, such as by implanting dopant (e.g., at least one N-type dopant or at least one P-type dopant) into the second semiconductor material 364 of the second base structure 362.

Referring next to FIG. 7B, a mask material 702 may be formed over the second base structure 362, and the mask material 702 may be patterned to form a patterned aperture 704 horizontally aligned with and vertically over the first doped region 606 of the second base structure 362. The mask material 702 may be patterned to define the patterned aperture 704 utilizing any suitable methodology. For instance, in some embodiments, a photoresist material is formed on or over the mask material 702, is patterned (e.g., photoexposed and developed), and then an opening formed in the patterned photoresist material is extended into the mask material 702 to form the patterned aperture 704. A remainder of the mask material 702 may be removed during subsequent processing stages. The mask material 702 may be formed of and include a dielectric material, such as a dielectric nitride material (e.g., silicide nitride).

Referring next to FIG. 7C, the patterned aperture 704 may be employed to form a trench 610 extending vertically into the first doped region 606 of the second semiconductor material 364 of the second base structure 362. In some embodiments, the trench 610 has a vertical depth (e.g., vertical height) at least substantially equal to a vertical thickness of the second semiconductor material 364. Furthermore, in one or more embodiments, the trench 610 has a horizontal width at least substantially equal to or less than the vertical thickness of the second semiconductor material 364. For instance, the horizontal width of the trench 610 may be at least partially dependent on the vertical thickness of the second semiconductor material 364. In some embodiments, the trench 610 has a width within a range of about 60 nm to about 500 nm. In additional embodiments, the trench 610 has a width within a range of about 500 nm to about 1000 nm. In some embodiments, the patterned aperture 704 and the trench 610 are filled with a sacrificial material that can be removed and replaced with the fourth interconnect structure 372 (FIG. 6). Furthermore, subsequent to the formation of the antenna diode structure 604, the remainder of the control circuitry structure 104 described above in regard to FIG. 3 and FIG. 5 may be formed, and the control circuitry structure 104 (FIG. 3) may be bonded to the memory array structure 102 (FIG. 3).

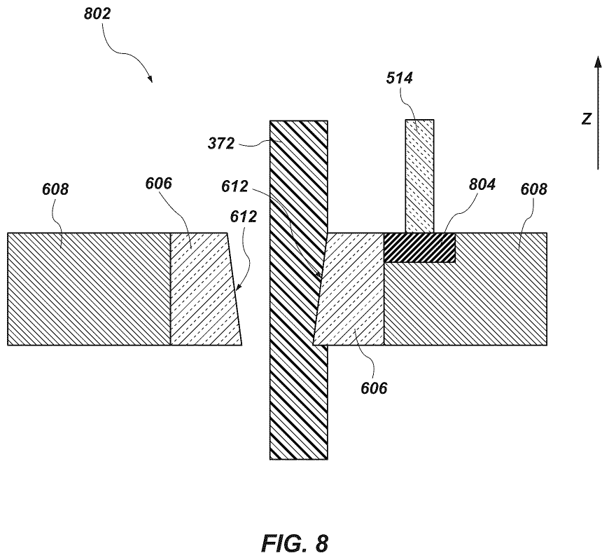

FIG. 8 shows a simplified, vertical cross-sectional view of an antenna diode structure 802 according to one or more embodiments of the disclosure. The antenna diode structure 802 depicted in FIG. 8 includes a one-sided antenna diode. In particular, the fourth interconnect structure 372 may be in contact with (e.g., in physical contact, electrical contact with) only one lateral sidewall 612 of the first doped region 606 of the antenna diode structure 802. For example, the fourth interconnect structure 372 may be offset relative a centerline of the trench 610 in a horizontal direction such that the fourth interconnect structure 372 contacts only one lateral sidewall 612 of the first doped region 606 of the antenna diode structure 802.

A portion of the first doped region 606 of the antenna diode structure 802 that is contacted by the fourth interconnect structure 372 may be in contact with or at least substantially proximate a third doped region 804 of the second semiconductor material 364. The third doped region 804 may be formed proximate an upper surface of the second semiconductor material 364 and may be contact with or interface with a third interconnect structure 514 of the control logic devices 516 (FIG. 5) of the control circuitry structure 104 (FIG. 3). In some embodiments, the third doped region 804 includes one of the conductively doped regions 502 (FIG. 5) of the transistors 368 (FIG. 5) of the control logic devices 516 (FIG. 5). For example, the third doped region 804 may form a portion of a transistor 368 (FIG. 5) of the control logic devices (FIG. 5).

Referring still to FIG. 8, as noted above, one of the first doped region 606 and the second doped region 608 is N-type doped, while the other of the first doped region 606 and the second doped region 608 is P-type doped. Furthermore, the third doped region 804 may be either N-type doped or P-type doped and may have any of the concentrations described herein.

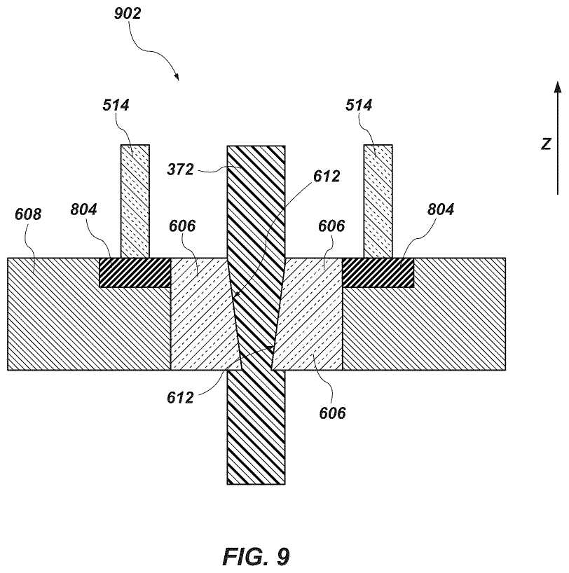

FIG. 9 shows a simplified, vertical cross-sectional view of an antenna diode structure 902 according to one or more embodiments of the disclosure. The antenna diode structure 902 includes a two-sided antenna diode. In particular, the fourth interconnect structure 372 may be in contact with (e.g., in physical contact, electrical contact with) both lateral sidewalls 612 of the first doped region 606 of the antenna diode structure 902. For example, the fourth interconnect structure 372 may be at least substantially centered about a vertical centerline of the trench 610 in a horizontal direction such that the fourth interconnect structure 372 contacts both of the lateral sidewalls 612 of the first doped region 606 of the antenna diode structure 902.

Both portions of the first doped region 606 of the antenna diode structure 802 that are contacted by the fourth interconnect structure 372 may be in contact with or at least substantially proximate respective third doped regions 804 of the second semiconductor material 364. The third doped regions 804 may be formed proximate an upper surface of the second semiconductor material 364 and may be contact with or interface with a respective third interconnect structure 514 of the control logic devices 516 (FIG. 5) of the control circuitry structure 104 (FIG. 3). In some embodiments, the third doped regions 804 include one of the conductively doped regions 502 (FIG. 5) of the transistors 368 (FIG. 5) of the control logic devices 516 (FIG. 5).

Referring still to FIG. 9, as noted above, one of the first doped region 606 and the second doped region 608 is N-type doped, while the other of the first doped region 606 and the second doped region 608 is P-type doped. Furthermore, the third doped regions 804 may be either N-type doped or P-type doped and may have any of the concentrations described herein.

Some embodiments include a microelectronic device including a first memory array structure having a first array region comprising first memory cells within a horizontal area thereof, each of the first memory cells including a first access device and a first storage node device vertically underlying and coupled to the first access device, a first control circuitry structure vertically overlying and attached to the first memory array structure at a boundary of the first memory array structure vertically closer to the first access devices of the first memory cells than to the first storage node devices of the first memory cells, the first control circuitry structure including: a base structure comprising a semiconductor material and an antenna diode structure formed within the semiconductor material. The antenna diode may include a first doped region of the semiconductor material, the first doped region having a trench extending vertically therethrough and a second doped region of the semiconductor material, the second doped region horizontally neighboring the first doped region and at least partially surrounding outer, horizontal boundaries of the first doped region. The microelectronic device may further include a cell plate over which the first memory array structure is oriented and attached, wherein the cell plate forms an electrode of a shared multi-capacitor structure and a contact assembly in contact with the cell plate and formed proximate a horizontal boundary of a patch region of the microelectronic device, the contact assembly comprising at least one interconnect structure in contact with the first doped region of the antenna diode structure.

One or more embodiments include method of forming a microelectronic device. The method may include forming a memory array structure including an array region having volatile memory cells within a horizontal area thereof, the volatile memory cells respectively comprising a vertical channel access device and a storage node device vertically underlying and coupled to the vertical channel access device, and forming a control circuitry structure comprising control logic circuitry, wherein forming the control circuitry structure comprises forming an antenna diode structure including forming a base structure comprising a semiconductor material, doping a first region of the semiconductor material to form a first doped region of the semiconductor material, doping a second region of the semiconductor material to a form a second doped region of the semiconductor material, the second doped region horizontally neighboring and contacting the first doped region; and forming a trench through the first doped region, the first doped region having lateral sidewalls defining horizontal boundaries of the trench. The method further includes bonding the control circuitry structure to a surface of the memory array structure vertically closer to the vertical channel access devices of the volatile memory cells than the storage node devices of the volatile memory cells and forming an interconnect structure vertically extending through at least a portion of the control circuitry structure and at least a portion of the memory array structure and contacting at least one lateral sidewall of first doped region of the antenna diode structure.

Some embodiments include microelectronic device including a memory array structure comprising an array region comprising memory cells within a horizontal area thereof, each of the memory cells comprising a vertically oriented access device and a storage node device vertically below and coupled to the vertically oriented access device, a control circuitry structure vertically above and dielectric-to-dielectric bonded to the first memory array structure, and an additional structure over which the memory array structure is oriented and attached. The additional structure may include a cell plate forming an electrode of a shared multi-capacitor structure, a base structure, and an isolation structure vertically overlying the base structure and vertically interposed between the base structure and the cell plate, wherein a minimum vertical distance between the cell plate and the base structure is within a range of about 1200 nm to about 10000 nm.

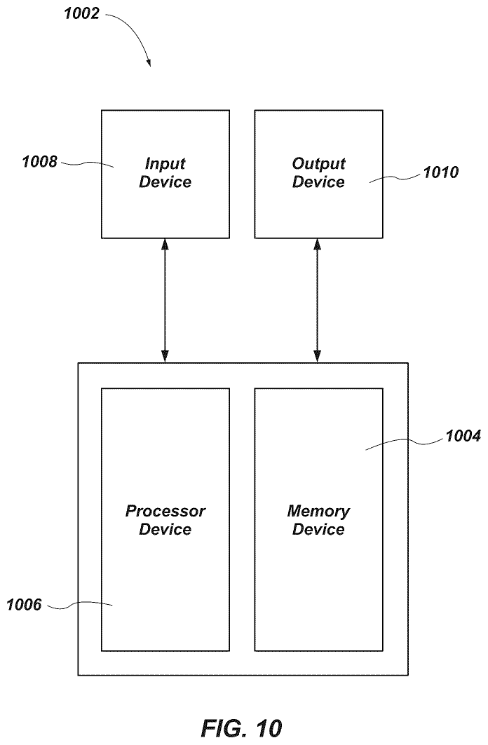

Microelectronic devices (e.g., the microelectronic device 100 (FIG. 3)) in accordance with embodiments of the disclosure may be used in embodiments of electronic systems of the disclosure. For example, FIG. 10 is a block diagram illustrating an electronic system 1002 according to embodiments of disclosure. The electronic system 1002 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPAD® or SURFACE® tablet, an electronic book, a navigation device, etc. The electronic system 1002 includes at least one memory device 1004. The memory device 1004 may comprise, for example, a microelectronic device (e.g., the microelectronic device 100 (FIG. 3)) previously described herein. The electronic system 1002 may further include at least one electronic signal processor device 1006 (often referred to as a “microprocessor”). The electronic signal processor device 1006 may, optionally, comprise a microelectronic device (e.g., the microelectronic device 100 (FIG. 3)) previously described herein. While the memory device 1004 and the electronic signal processor device 1006 are depicted as two (2) separate devices in FIG. 10, in additional embodiments, a single (e.g., only one) memory/processor device having the functionalities of the memory device 1004 and the electronic signal processor device 1006 is included in the electronic system 1002. In such embodiments, the memory device 1004/electronic signal processor device 1006 includes a microelectronic device (e.g., the microelectronic device 100 (FIG. 3)) previously described herein. The electronic system 1002 may further include one or more input devices 1008 for inputting information into the electronic system 1002 by a user, such as, for example, a mouse or other pointing device, a keyboard, a touchpad, a button, or a control panel. The electronic system 1002 may further include one or more output devices 1010 for outputting information (e.g., visual or audio output) to a user such as, for example, a monitor, a display, a printer, an audio output jack, a speaker, etc. In some embodiments, the input device 1008 and the output device 1010 include a single touchscreen device that can be used both to input information to the electronic system 1002 and to output visual information to a user. The input device 1008 and the output device 1010 may communicate electrically with one or more of the memory device 1004 and the electronic signal processor device 1006.

The structures, devices, and methods of the disclosure advantageously facilitate one or more of improved microelectronic device performance, reduced costs (e.g., manufacturing costs, material costs), increased miniaturization of components, and greater packaging density as compared to conventional structures, conventional devices, and conventional methods. The structures, devices, and methods of the disclosure may also improve scalability, efficiency, and simplicity as compared to conventional structures, conventional devices, and conventional methods.

While the disclosure is susceptible to various modifications and alternative forms, specific embodiments have been shown by way of example in the drawings and have been described in detail herein. However, the disclosure is not limited to the particular forms disclosed. Rather, the disclosure is to cover all modifications, equivalents, and alternatives falling within the scope of the following appended claims and their legal equivalent. For example, elements and features disclosed in relation to one embodiment may be combined with elements and features disclosed in relation to other embodiments of the disclosure.

The embodiments of the disclosure described above and illustrated in the accompanying drawings do not limit the scope of the disclosure, which is encompassed by the scope of the appended claims and their legal equivalents. Any equivalent embodiments are within the scope of this disclosure. Indeed, various modifications of the disclosure, in addition to those shown and described herein, such as alternate useful combinations of the elements described, will become apparent to those skilled in the art from the description. Such modifications and embodiments also fall within the scope of the appended claims and equivalents.

What is claimed is:

1. A microelectronic device, comprising:
a first memory array structure comprising a first array region comprising first memory cells within a horizontal area thereof, each of the first memory cells comprising a first access device and a first storage node device vertically underlying and coupled to the first access device;
a first control circuitry structure vertically overlying and attached to the first memory array structure at a boundary of the first memory array structure vertically closer to the first access devices of the first memory cells than to the first storage node devices of the first memory cells, the first control circuitry structure comprising:
a base structure comprising a semiconductor material; and
an antenna diode structure formed within the semiconductor material and comprising:
a first doped region of the semiconductor material, the first doped region having a trench extending vertically therethrough; and
a second doped region of the semiconductor material, the second doped region horizontally neighboring the first doped region and at least partially surrounding outer, horizontal boundaries of the first doped region;
a cell plate over which the first memory array structure is oriented and attached, wherein the cell plate forms an electrode of a shared multi-capacitor structure; and
a contact assembly in contact with the cell plate and formed proximate a horizontal boundary of a patch region of the microelectronic device, the contact assembly comprising at least one interconnect structure in contact with the first doped region of the antenna diode structure.

2. The microelectronic device of claim 1, wherein the first doped region is doped with one of an N-dopant or a P-dopant and the second doped region is doped with the other of an N-dopant or a P-dopant.

3. The microelectronic device of claim 1, wherein the first control circuitry structure comprises control logic devices formed on the semiconductor material.

4. The microelectronic device of claim 3, wherein the antenna diode structure further comprises at least one third doped region formed within the semiconductor material and operably coupled to the second doped region and at least one control logic device.

5. The microelectronic device of claim 4, wherein the third doped region comprises a portion of a transistor of the at least one control logic device.

6. The microelectronic device of claim 1, further comprising:
a second base structure; and
an isolation structure vertically overlying the second base structure and vertically interposed between the base structure and the cell plate.

7. The microelectronic device of claim 6, wherein a minimum distance between the cell plate and the base structure is within a range of from about 1000 nm to about 10000 nm.

8. The microelectronic device of claim 1, further comprising semiconductor material overlying the cell plate.

9. The microelectronic device of claim 8, wherein the contact assembly extends through the semiconductor material.

10. The microelectronic device of claim 1, wherein the contact assembly comprises structures from both the first memory array structure and the first control circuitry structure.

11. The microelectronic device of claim 1, wherein the at least one interconnect structure contacts only one lateral sidewall of the first doped region defining the trench.

12. The microelectronic device of claim 1, wherein the at least one interconnect structure contacts two lateral sidewalls of the first doped region defining the trench.

13. The microelectronic device of claim 1, wherein the at least one interconnect structure vertically overlaps with both the first memory array structure and the first control circuitry structure.

14. The microelectronic device of claim 1, further comprising:
a second memory array structure comprising a second array region comprising second memory cells within a horizontal area thereof, each of the second memory cells comprising a second access device and a second storage node device vertically underlying and coupled to the second access device, the second memory array structure being oriented over and attached to the cell plate and horizontally neighboring the first memory array structure and first control circuitry structure; and
a second control circuitry structure vertically overlying and attached to the second memory array structure at a boundary of the second memory array structure vertically closer to the second access devices of the second memory cells than the second storage node devices of the second memory cells.

15. A method of forming a microelectronic device, comprising:
forming a memory array structure including an array region having volatile memory cells within a horizontal area thereof, the volatile memory cells respectively comprising a vertical channel access device and a storage node device vertically underlying and coupled to the vertical channel access device;
forming a control circuitry structure comprising control logic circuitry, wherein forming the control circuitry structure comprises forming an antenna diode structure comprising:
forming a base structure comprising a semiconductor material;
doping a first region of the semiconductor material to form a first doped region of the semiconductor material;
doping a second region of the semiconductor material to a form a second doped region of the semiconductor material, the second doped region horizontally neighboring and contacting the first doped region; and
forming a trench through the first doped region, the first doped region having lateral sidewalls defining horizontal boundaries of the trench;
bonding the control circuitry structure to a surface of the memory array structure vertically closer to the vertical channel access devices of the volatile memory cells than the storage node devices of the volatile memory cells; and
forming an interconnect structure vertically extending through at least a portion of the control circuitry structure and at least a portion of the memory array structure and contacting at least one lateral sidewall of first doped region of the antenna diode structure.

16. The method of claim 15, wherein forming the interconnect structure comprises forming the interconnect structure to contact only one of the lateral sidewalls of the first doped region of the antenna diode structure.

17. The method of claim 15, wherein forming the interconnect structure comprises forming the interconnect structure to contact two of the lateral sidewalls of the first doped region of the antenna diode structure.

18. The method of claim 15, wherein bonding the control circuitry structure to the memory array structure comprises bonding the control circuitry structure over the memory array structure through dielectric-to-dielectric bonding between dielectric material of the memory array structure and additional dielectric material of the control circuitry structure.

19. The method of claim 15, further comprising:
forming a cell plate overlying a side of the memory array structure opposite the control circuitry structure;
forming a first dielectric structure overlying the cell plate; and
bonding the first dielectric structure to a second dielectric structure overlying a second base structure through dielectric-to-dielectric bonding between the first dielectric structure and the second dielectric structure such that a minimum distance between the cell plate and the second base structure is within a range of about 1200 nm and about 10000 nm.

20. A microelectronic device, comprising:
a memory array structure comprising an array region comprising memory cells within a horizontal area thereof, each of the memory cells comprising a vertically oriented access device and a storage node device vertically below and coupled to the vertically oriented access device;
a control circuitry structure vertically above and dielectric-to-dielectric bonded to the memory array structure; and
an additional structure over which the memory array structure is oriented and attached, the additional structure comprising:
a cell plate forming an electrode of a shared multi-capacitor structure;
a base structure; and
an isolation structure vertically overlying the base structure and vertically interposed between the base structure and the cell plate, wherein a minimum vertical distance between the cell plate and the base structure is within a range of about 1200 nm to about 10000 nm.
